(19) United States
(12) Patent Application Publication
(10) Pub. No.: US 2015/0179930 A1
(43) Pub. Date: Jun. 25, 2015

(54) Schottky Barriers for Resistive Random Access Memory Cells

(71) Applicant: Intermolecular Inc., San Jose, CA (US)

(72) Inventors: Federico Nardi, Palo Alto, CA (US); Yun Wang, San Jose, CA (US)

(73) Assignee: Intermolecular Inc., San Jose, CA (US)

(21) Appl. No.: 14/138,462

(22) Filed: Dec. 23, 2013

(51) Int. Cl. H01L 45/00

(52) U.S. Cl. CPC H01L 45/1253; H01L 45/146; H01L 45/1608

(57) ABSTRACT

Provided are resistive random access memory (ReRAM) cells having Schottky barriers and methods of fabricating such ReRAM cells. Specifically, a ReRAM cell includes two Schottky barriers, one barrier limiting an electrical current through the variable resistance layer in one direction and the other barrier limiting a current in the opposite direction. This combination of the two Schottky barriers provides current compliance during set operations and limits undesirable current overshoots during reset operations. The Schottky barriers' heights are configured to match the resistive switching characteristics of the cell. Conductive layers of the ReRAM cells operable as electrodes may be used to form these Schottky barriers together with semiconductor layers. These semiconductor layers may be different components from a variable resistance layer and, in some embodiments, may be separated by intermediate conductive layers from the variable resistance layers.

### BACKGROUND

Nonvolatile memory is computer memory capable of retaining stored information even when unpowered. Non-volatile memory is typically used for secondary storage or long-term persistent storage and may be used in addition to volatile memory, which loses the stored information when unpowered. Nonvolatile memory can be permanently integrated into computer systems (e.g., solid state hard drives) or can take the form of removable and easily transportable memory cards (e.g., USB flash drives). Nonvolatile memory is becoming more popular because of its small size/high density, low power consumption, fast read and write rates, retention, and other characteristics.

Flash memory is a common type of nonvolatile memory because of its high density and low fabrication costs. Flash memory is a transistor-based memory device that uses multiple gates per transistor and quantum tunneling for storing the information on its memory device. Flash memory uses a block-access architecture that can result in long access, erase, and write times. Flash memory also suffers from low endurance, high power consumption, and scaling limitations.

The constantly increasing speed of electronic devices and storage demand drive new requirements for nonvolatile memory. For example, nonvolatile memory is expected to replace hard drives in many new computer systems. However, transistor-based flash memory is often inadequate to meet the requirements for nonvolatile memory. New types of memory, such as resistive random access memory (ReRAM), are being developed to meet these demands and requirements.

### SUMMARY

Provided are resistive random access memory (ReRAM) cells having Schottky barriers and methods of fabricating such ReRAM cells. Specifically, a ReRAM cell includes two Schottky barriers, one limiting an electrical current through the variable resistance layer in one direction and the other one limiting a current in the opposite direction. This combination of the two Schottky barriers provides current compliance during set operations and limits undesirable current overshoots during reset operations. The Schottky barriers' heights may be configured to match the resistive switching characteristics of the cell. Conductive layers of the ReRAM cells operable as electrodes may be used to form these Schottky barriers together with semiconductor layers. These semiconductor layers may be different components from a variable resistance layer and, in some embodiments, may be separated by intermediate conductive layers from the variable resistance layers.

In some embodiments, a ReRAM cell includes a first conductive layer, a second conductive layer, a variable resistance layer, a first semiconductor layer, and a second semiconductor layer. The first conductive layer and the second conductive layer are operable as electrodes. The variable resistance layer is disposed between the first conductive layer and the second conductive layer. The first semiconductor layer is disposed between the first conductive layer and the variable resistance layer. The second semiconductor layer is disposed between the second conductive layer and the variable resistance layer. The first semiconductor layer and the first conductive layer form a first Schottky barrier limiting an electrical current flow from the first conductive layer to the second conductive layer. The second semiconductor layer and the second conductive layer form a second Schottky barrier limiting an electrical current flow from the second conductive layer to the first conductive layer. In other words, the first Schottky barrier is configured to limit the electrical current flowing in one direction, while the second Schottky barrier is configured to limit the electrical current flowing in the opposite direction. For example, the first Schottky barrier may be configured to limit the electrical current during a set operation while the second Schottky barrier is configured to limit the electrical current during a reset operation.

In some embodiments, the first semiconductor layer may directly interface the variable resistance layer. The second semiconductor layer directly may also interface the variable resistance layer in the same or other embodiments. Alternatively, the ReRAM cell also includes a first intermediate conductive layer disposed between the first semiconductor layer and the variable resistance layer. Furthermore, the ReRAM cell may include a second intermediate conductive layer disposed between the second semiconductor layer and the variable resistance layer. In some embodiments, only one intermediate conductive layer is present. For example, the ReRAM cell may include a second intermediate conductive layer disposed between the second semiconductor layer and the variable resistance layer while the first semiconductor layer directly interfaces the variable resistance layer.

In some embodiments, the first conductive layer and/or the second conductive layer includes one of aluminum, copper, gold, silver, nickel, palladium, platinum, chromium, molybdenum, tungsten, titanium, or indium. The first semiconductor layer and/or the second semiconductor layer includes one of silicon, a silicon containing compound, germanium, a germanium containing compound, an aluminum containing compound, a boron containing compound, a gallium containing compound, an indium containing compound, a cadmium containing compound, a zinc containing compound, a lead containing compound, or a tin containing compound. In some embodiments, the first semiconductor layer includes gallium arsenide or gallium phosphide. Alternatively, the first semiconductor layer includes crystalline silicon. At least a portion of this first semiconductor layer may be doped with one of phosphorus, boron, or arsenic.

In some embodiments, the ReRAM cell is a bi-polar cell. The first Schottky barrier may be configured to pass a set electrical current flowing from the first conductive layer to the second conductive layer when a set voltage is applied between the first conductive layer and the second conductive layer. The set electrical current and the set voltage are determined by resistive switching characteristics of the ReRAM cell. In some embodiments, the second Schottky barrier is configured to pass a reset electrical current flowing from the second conductive layer to the first conductive layer when a reset voltage is applied between the first conductive layer and the second conductive layer. The reset electrical current and the reset voltage are determined by resistive switching characteristics of the ReRAM cell. The first Schottky barrier may have the same current limiting characteristics as the second Schottky barrier. Alternatively, the first Schottky barrier may have different current limiting characteristics than the second Schottky barrier.

In some embodiments, the variable resistance layer has a variable composition in the direction from the first conductive layer to the second conductive layer. The variable resistance layer may include one of silicon oxide, aluminum oxide, hafnium oxide, or zirconium oxide. The concentration of oxygen may be less at the surface of the variable resistance layer facing to the first conductive layer than at a surface of the variable resistance layer facing the second conductive layer.

In some embodiments, the first Schottky barrier and the second Schottky barrier retain current limiting characteristics after being exposed to at least about 600° C. for at least about 1 minute. For example, the ReRAM cell including the first Schottky barrier and the second Schottky barrier may be annealed using these conditions.

Also provided is a method of fabricating a ReRAM cell. The method may involve forming a first conductive layer, forming a first semiconductor layer over the first conductive layer, forming a variable resistance layer over the first semiconductor layer, forming a second semiconductor layer over the variable resistance layer, and forming a second conductive layer over the second semiconductor layer. The first conductive layer and the second conductive layer are operable as electrodes. The first semiconductor layer and the first conductive layer form a first Schottky barrier limit a current flow from the first conductive layer to the second conductive layer. The second semiconductor layer and the second conductive layer form a second Schottky barrier limit a current flow from the second conductive layer to the first conductive layer.

These and other embodiments are described further below with reference to the figures.

### BRIEF DESCRIPTION OF THE DRAWINGS

To facilitate understanding, the same reference numerals have been used, where possible, to designate common components presented in the figures. The drawings are not to scale and the relative dimensions of various elements in the drawings are depicted schematically and not necessarily to scale. Various embodiments can readily be understood by considering the following detailed description in conjunction with the accompanying drawings, in which:

FIG. 1A illustrates a schematic representation of a ReRAM cell prior to its initial forming operation, in accordance with some embodiments.

FIGS. 1B and 1C illustrate schematic representations of the ReRAM cell in its high resistive state (HRS) and low resistive state (LRS), in accordance with some embodiments.

FIG. 2A illustrates a plot of a current passing through a unipolar ReRAM cell as a function of a voltage applied to the ReRAM cell, in accordance with some embodiments.

FIG. 2B illustrates a plot of a current passing through a bipolar ReRAM cell as a function of a voltage applied to the ReRAM cell, in accordance with some embodiments.

FIG. 3A is a plot of a typical I-V characteristic of a Schottky barrier, in accordance with some embodiments.

FIG. 3B is a plot of I-V characteristics of two Schottky barriers, in accordance with some embodiments.

FIG. 3C is a plot of I-V characteristics of two Schottky barriers connected in series in an inverted manner, in accordance with some embodiments.

FIG. 3D is a combined plot of I-V characteristics of a bipolar ReRAM cell and a stack of two Schottky barriers connected in series with each other (in an inverted manner) and a variable resistance layer of the bipolar ReRAM cell, in accordance with some embodiments.

FIG. 4A is a schematic illustration of a ReRAM cell without any interface layers between its variable resistance layer and two semiconductor layers forming Schottky barriers, in accordance with some embodiments.

FIG. 4B is a schematic illustration of another ReRAM cell having two interface layers such that each interface layer is disposed between a variable resistance layer and one of the semiconductor layers forming Schottky barriers, in accordance with some embodiments.

FIG. 5 illustrates a process flow chart corresponding to a method of fabricating a resistive random access memory cell including two inverted Schottky barriers disposed in a stack and connected in series with a variable resistance layer, in accordance with some embodiments.

FIGS. 6A and 6B illustrate schematic views of memory arrays including multiple ReRAM cells, in accordance with some embodiments.

### DETAILED DESCRIPTION

A detailed description of various embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

### Introduction

A ReRAM cell exhibiting resistive switching characteristics generally includes multiple layers formed into a stack, such as a “metal-insulator-metal” (MIM) stack. The stack includes two conductive layers operable as electrodes, which are identified as “M” and may include a metal. In some embodiments, these conductive layers may o include other types of conductive materials, such as doped silicon. The stack also includes an insulator layer provided in between the two electrodes and identified as “I”. The insulator layer changes its resistive properties when certain switching voltages are applied to the layer or, more generally, to the ReRAM cell including this layer. Due to its variable resistance characteristics, the insulator layer may be also referred to as a variable resistance layer. These changes in resistive properties are used to store data. For example, when two different resistive states are identified (e.g., a high resistive state and a low resistive state) for a ReRAM cell, one state may be associated with a logic “zero”, while the other state may be associated with a logic “one” value. Similar approaches may be used when three or more resistive states may be identified for the same ReRAM cell leading to various multibit architectures.

The switching voltages may be applied as series of pulses and may be generally referred to as switching voltage profiles or, more specifically, set voltage profiles and reset voltage profiles. For example, a switching voltage pulse may be used to change (“set” or “reset”) the resistive state followed by a smaller reading voltage pulse to determine the current state of the ReRAM cell at that time. Unlike the switching voltage pulse, the reading pulse is specifically configured to avoid changing the resistive state of the ReRAM cell and is configured only to determine the current state. The switching pulse may be repeated if the desired resistive state is not reached. The switching pulses may alternate with the reading pulses for feedback control. The switching pulses may vary from one to another based on their potential (e.g., a gradual increase in the potential), duration, and other characteristics. The reading pulses may be the same. The process of applying the switching pulses and reading pulses may continue until the desired resistive state is reached.

The change in resistance of the variable resistance layer is a dynamic process that needs to be well controlled to prevent over-programming. For example, when the variable resistance layer is switched from its high resistive state (HRS) to its low resistive state (LRS), a rapid drop in resistance associated with this switch may cause an excessive current through the variable resistance layer and/or voltage drop in between the electrodes. The over-programming occurs when the change in resistance continues after the variable resistance layer reaches its desirable resistance.

One approach to prevent over-programming is to use very short switching pulses, e.g., about 50 nanoseconds, followed by a reading pulse. If the desired resistive state is not reached, another pulse is applied. The process of applying switching and reading pulses may be repeated until the desired resistance is not reached. However, shorter pulses have their own inherent limitations, such as requiring more pulses and/or higher voltages to achieve the same switching result, which may consume more power than fewer, longer, and/or lower-voltage pulses. Furthermore, even during a relatively short switching pulse, the change in resistance may be sufficiently large to result in current spiking and over-programming. In some embodiments, the difference in resistances between the LRS and the HRS may be more than an order of magnitude to allow the read pulses to easily differentiate between the two states.

Another approach to prevent current spiking and over-programming is to add a constant resistor connected in series with the variable resistance layer. The resistor limits the current through the variable resistance layer and effectively functions as a voltage divider within the ReRAM cell. However, an additional voltage drop associated with such a resistor requires more voltage being applied to the cell containing this resistor in order to achieve a desired voltage across the variable resistance layer. Applying high voltage may result in undesirably high power consumption.

Provided are ReRAM cell with Schottky barriers that limit electrical currents flowing through the cells in both directions. Specifically, a ReRAM cell includes two Schottky barriers, one Schottky barrier limiting an electrical current through the cells, or more specifically, through the variable resistance layer in one direction (e.g., from a first electrode to a second electrode), while the other Schottky barrier limits an electrical current in the opposite direction (e.g., from the second electrode to the first electrode). In other words, the two Schottky barriers are connected in series with the variable resistance layer and oriented inversely with respect to each other. This combination of the two Schottky barriers in the same ReRAM cell provides current compliance during set operations and limits undesirable current overshoots during reset operations. The Schottky barriers' heights may be configured to match the resistive switching characteristics of the cell during each of these two switching operations.

A Schottky barrier creates a potential energy barrier for electrons formed at a metal-semiconductor junction or, more generally, conductive layer-semiconductor layer interface. It may have rectifying characteristics, such as a barrier height. The barrier may be high enough that there is a depletion region in the semiconductor layer, near the interface with the conductive layer. This gives the barrier a high resistance when a small voltage bias is applied to it. Under a large voltage bias, the electrical current flowing through the barrier is essentially governed by the laws of thermionic emission, combined with the fact that the Schottky barrier is fixed relative to the conductive layer's Fermi level.

Under forward bias, there are many thermally excited electrons in the semiconductor layer that are able to pass over the barrier. The passage of these electrons over the barrier (without any electrons coming back) corresponds to a current in the opposite direction. The current rises very rapidly with bias; however, at high biases the series resistance of the semiconductor layer can start to limit the current.

Under reverse bias, there is a small leakage current as some thermally excited electrons in the conductive layer have enough energy to surmount the barrier. To first approximation, this current should be constant; however, the current rises gradually with reverse bias due to weak barrier lowering. At very high biases, the depletion region breaks down. In some embodiments, the current-voltage relationship of a Schottky barrier may be qualitatively the same as with a p-n junction, however the physical process is different. Overall, the Schottky barrier results in both very fast switching and low forward voltage drop.

A conductive layer of the Schottky barrier may be formed from molybdenum, platinum, chromium, tungsten, and silicides (e.g., palladium silicide and platinum silicide). A semiconductor layer may be formed from n-type silicon. The conductive layer effectively functions as the anode, while the semiconductor layer effectively functions as the cathode. The materials of the semiconductor layer and the conductive layer determine the forward voltage of the Schottky barrier. Many n- and p-type semiconductors can develop Schottky barriers. The p-type semiconductors typically have much lower forward voltages than the n-type semiconductors. In some embodiments, the forward voltage may be between about 0.5-0.7 V. Titanium silicide and other refractory silicides may be used because of their high temperature stability. With increased doping levels of the semiconductor layer, the width of the depletion region drops. Below certain width the charge carriers can tunnel through the depletion region. At very high doping levels, the junction does not behave as a rectifier anymore and becomes an ohmic contact.

In some embodiments, conductive layers of the ReRAM cells, which are operable as electrodes, may be used to form these Schottky barriers together with semiconductor layers. In other words, each Schottky barrier may be formed by a conductive layer and a semiconductor layer. These semiconductor layers forming the Schottky barriers of the ReRAM cell may be different components from a variable resistance layer. In some embodiments, one or both Schottky barriers may be separated by intermediate conductive layers from the variable resistance layers.

Examples of ReRAM Cells and their Switching Mechanisms

A brief description of ReRAM cells is provided for context and better understanding of various features associated with Schottky barriers in the ReRAM cells. As stated above, a ReRAM cell includes a dielectric material formed into a layer exhibiting resistive switching characteristics. A dielectric, which is normally insulating, can be made to conduct through one or more conductive paths formed after application of a voltage. The conductive path formation can arise from different mechanisms, including defects, metal migration, and other mechanisms further described below. Once one or more conductive paths (e.g., filaments) are formed in the dielectric component of a memory device, these conductive paths may be reset (or broken resulting in a high resistance) or set (or re-formed resulting in a lower resistance) by applying certain voltages. Without being restricted to any particular theory, it is believed that resistive switching corresponds to migration of defects within the variable resistance layer and, in some embodiments, across one interface formed by the resistive switching voltage, when a switching voltage is applied to the layer.

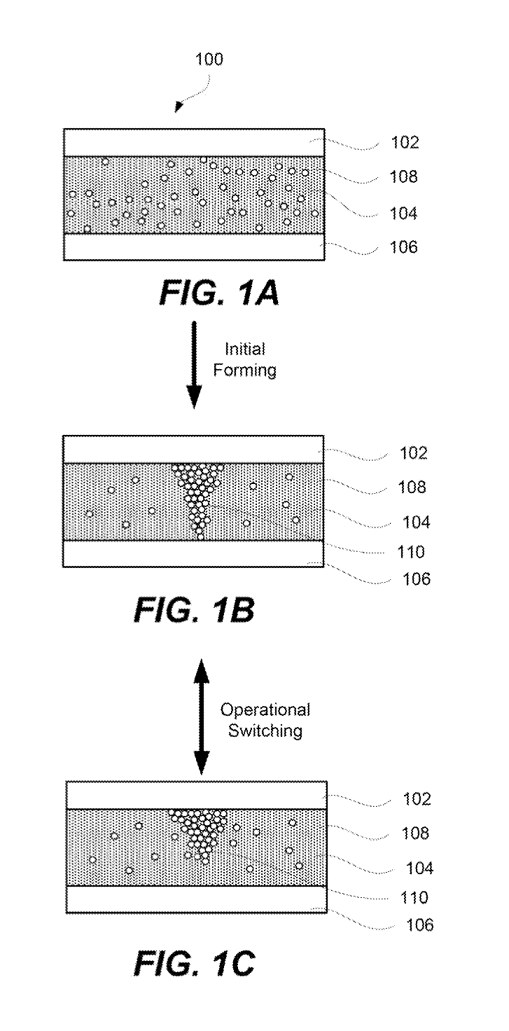

FIG. 1A illustrates a schematic representation of ReRAM cell 100 including first electrode 102, second electrode 106, and variable resistance layer 104 disposed in between first electrode 102 and second electrode 106. It should be noted that the “first” and “second” references for electrodes 102 and 106 are used solely for differentiation and not to imply any processing order or particular spatial orientation of these electrodes. ReRAM cell 100 may also include other components, such as an embedded resistor, diode, diffusion barrier layer, and other components. ReRAM cell 100 is sometimes referred to as a memory element or a memory unit.

First electrode 102 and second electrode 106 may be used as conductive lines within a memory array or other types of devices that ReRAM cell is integrated into. As such, electrode 102 and 106 are generally formed from conductive materials. As stated above, one of the electrodes may be reactive electrode and act as a source and as a reservoir of defects for the variable resistance layer. That is, defects may travel through an interface formed by this electrode with the variable resistance layer (i.e., the reactive interface).

Variable resistance layer 104 may be initially formed from a dielectric material and later made to conduct through one or more conductive paths formed within the layer by applying first a forming voltage and then a switching voltage. To provide this resistive switching functionality, variable resistance layer 104 includes a concentration of electrically active defects 108, which may be at least partially provided into the layer during its fabrication. For example, some atoms may be absent from their native structures (i.e., creating vacancies) and/or additional atoms may be inserted into the native structures (i.e., creating interstitial defects). Charge carriers may be also introduced as dopants, stressing lattices, and other techniques. Regardless of the types all charge carriers are referred to as defects 108.

FIG. 1A is a schematic representation of ReRAM cell 100 prior to initial formation of conductive paths, in accordance with some embodiments. Variable resistance layer 104 may include some defects 108. Additional defects 108 may be provided within first electrode 102 and may be later transferred to variable resistance layer 104 during the formation operation. In some embodiments, the variable resistance layer 104 has substantially no defects prior to forming operation and all defects are provided from first electrode 102 during forming. Second electrode 106 may or may not have any defects. It should be noted that regardless of the presence or absence of defects in second electrode 106, in some embodiments substantially no defects are exchanged between second electrode 106 and variable resistance layer 104 during forming and/or switching operations.

During the forming operation, ReRAM cell 100 changes its structure from the one shown in FIG. 1A to the one shown in FIG. 1B. This change corresponds to defects 108 being arranged into one or more continuous paths within variable resistance layer 104 as, for example, schematically illustrated in FIG. 1B. Without being restricted to any particular theory, it is believed that defects 108 can be reoriented within variable resistance layer 104 to form these conductive paths as, for example, schematically shown in FIG. 1B. Furthermore, some or all defects 108 forming the conductive paths may enter variable resistance layer 104 from first electrode 102. For simplicity, all these phenomena are collectively referred to as reorientation of defects within ReRAM cell 100. This reorientation of defects 108 occurs when an above-threshold forming voltage is applied to electrodes 102 and 106. In some embodiments, the forming operation is conducted at elevated temperatures to enhance mobility of the defects within ReRAM cell 100. In general, the one-time forming operation is considered to be a part of the fabrication of ReRAM cell 100, while subsequent repeated resistive switching is considered to be a part of operation of ReRAM cell 100.

Resistive switching involves breaking and reforming conductive paths through variable resistance layer 104, i.e., switching between the state schematically illustrated in FIG. 1B and the state schematically illustrated in FIG. 1C. The resistive switching is performed by applying switching voltages to electrodes 102 and 106. Depending on magnitude and polarity of these voltages, conductive path 110 may be broken (increasing the resistance) or restored (decreasing the resistance). These voltages may be substantially lower than the forming voltages (i.e., voltages used in the forming operation) since forming must create the entire conductive path 110 and switching only breaks and restores a relatively small part of it, and therefore much less mobility of defects is needed during switching operations. For example, hafnium oxide based resistive layers may need about 7 Volts during their forming but can be switched using voltages less than 4 Volts.

The state of variable resistance layer 104 illustrated in FIG. 1B is referred to as a low resistive state (LRS), while the state illustrated in FIG. 1C is referred to as a high resistive state (HRS). The resistance difference between the LRS and HRS is due to different number, extent, and/or conductivity of conductive paths that exists in these states, i.e., variable resistance layer 104 has more conductive paths and/or less resistive conductive paths when it is in the LRS than when it is in the HRS. It should be noted that variable resistance layer 104 may still have some conductive paths while it is in the HRS, but these conductive paths are fewer, shorter, and/or more resistive than the ones corresponding to the LRS.

When switching from its LRS to HRS, which is often referred to as a reset operation, variable resistance layer 104 may release some defects into first electrode 102. Furthermore, there may be some mobility of defects within variable resistance layer 104. This may lead to thinning and, in some embodiments, breakages of conductive paths as shown in FIG. 1C. Depending on mobility within variable resistance layer 104 and diffusion through the interface formed by variable resistance layer 104 and first electrode 102, the conductive paths may break closer to the interface with second electrode 106, somewhere within variable resistance layer 104, or at the interface with first electrode 102. This breakage generally does not correspond to complete dispersion of defects forming these conductive paths and may be a self-limiting process, i.e., the process may stop after some initial breakage occurs.

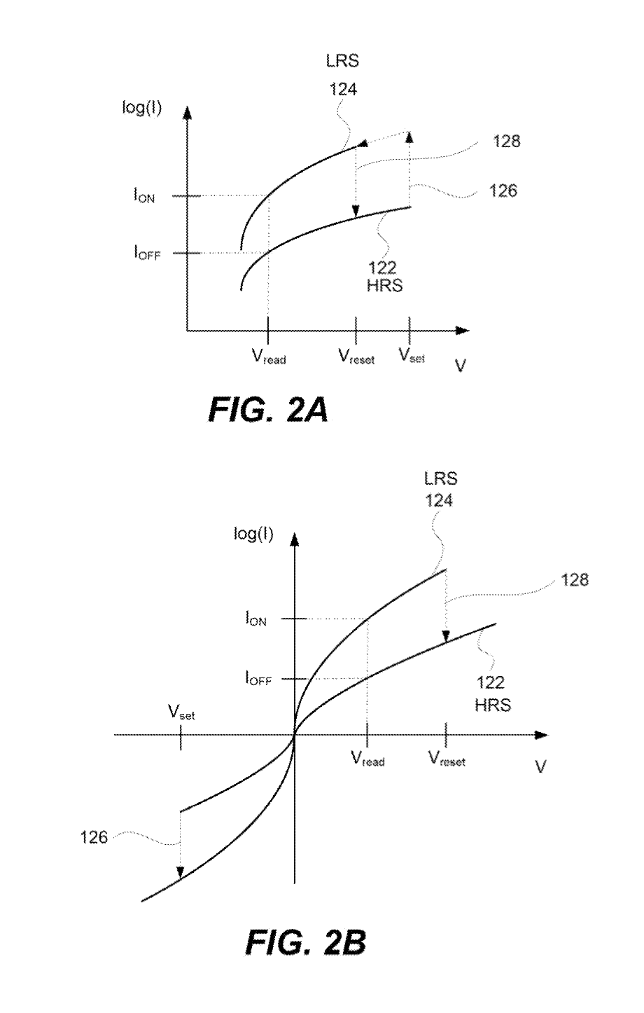

When switching from its HRS to LRS, which is often referred to as a set operation, variable resistance layer 104 may receive some defects from first electrode 102. Similar to the reset operation described above, there may be some mobility of defects within variable resistance layer 104. This may lead to thickening and, in some embodiments, reforming of conductive paths as shown in FIG. 1B. In some embodiments, a voltage applied to electrodes 102 and 106 during the set operation has the same polarity as a voltage applied during the reset operation. This type of switching is referred to as unipolar switching. Alternatively, a voltage applied to electrodes 102 and 106 during the set operation may have different polarity as a voltage applied during the reset operation. This type of switching is referred to as bipolar switching. Setting and resetting operations may be repeated multiple times as will now be described with reference to FIGS. 2A and 2B.

Specifically, FIG. 2A illustrates a plot of a current passing through a unipolar ReRAM cell as a function of a voltage applied to the ReRAM cell, in accordance with some embodiments. FIG. 2B illustrates the same type of plot for a bipolar ReRAM cell, in accordance with some embodiments. The HRS is defined by line 122, while the LRS is defined by 124 in both plots. Each of these states is used to represent a different logic state, e.g., the HRS may represent logic one (“1”) and LRS representing logic zero (“0”) or vice versa. Therefore, each ReRAM cell that has two resistive states may be used to store one bit of data. It should be noted that some ReRAM cells may have three and even more resistive states allowing multi-bit storage in the same cell.

The overall operation of the ReRAM cell may be divided into a read operation, set operation (i.e., turning the cell “ON” by changing from its HRS to LRS), and reset operation (i.e., turning the cell “OFF” by changing from its LRS to HRS). During the read operation, the state of the ReRAM cell or, more specifically, the resistive state of its resistance of variable resistance layer can be sensed by applying a sensing voltage to its electrodes. The sensing voltage is sometimes referred to as a “READ” voltage or simply a reading voltage and indicated as VREAD in FIG. 2. If the ReRAM cell is in its HRS (represented by line 122 in FIGS. 2A and 2B), the external read and write circuitry connected to the electrodes will sense the resulting “OFF” current (IOFF) that flows through the ReRAM cell. As stated above, this read operation may be performed multiple times without changing the resistive state (i.e., switching the cell between its HRS and LRS). In the above example, the ReRAM cell should continue to output the “OFF” current (IOFF) when the read voltage (V_{READ}) is applied to the electrodes for the second time, third time, and so on.

Continuing with the above example, when it is desired to turn “ON” the cell that is currently in the HRS switch, a set operation is performed. This operation may use the same read and write circuitry to apply a set voltage (V_{SET}) to the electrodes. Applying the set voltage forms one or more conductive paths in the variable resistance layer as described above with reference to FIGS. 1B and 1C. The switching from the HRS to LRS is indicated by dashed line 126 in FIGS. 2A and 2B. The resistance characteristics of the ReRAM cell in its LRS are represented by line 124. When the read voltage (V_{READ}) is applied to the electrodes of the cell in this state, the external read and write circuitry will sense the resulting “ON” current (ION) that flows through the ReRAM cell. Again, this read operation may be performed multiple times without switching the state of the ReRAM cell.

At some point, it may be desirable to turn “OFF” the ReRAM cell by changing its state from the LRS to HRS. This operation is referred to as a reset operation and should be distinguished from set operation during which the ReRAM cell is switched from its HRS to LRS. During the reset operation, a reset voltage (V_{RESET}) is applied to the ReRAM cell to break the previously formed conductive paths in the variable resistance layer. Switching from a LRS to HRS is indicated by dashed line 128. Detecting the state of the ReRAM cell while it is in its HRS is described above.

Overall, the ReRAM cell may be switched back and forth between its LRS and HRS many times. Read operations may be performed in each of these states (between the switching operations) one or more times or not performed at all. It should be noted that application of set and reset voltages to change resistive states of the ReRAM cell involves complex mechanisms that are believed to involve localized resistive heating as well as mobility of defects impacted by both temperature and applied potential.

In some embodiments, the set voltage (V_{SET}) is between about 100 mV and 10V or, more specifically, between about 500 mV and 5V. The length of set voltage pulses (t_{SET}) may be less than about 100 milliseconds or, more specifically, less than about 5 milliseconds and even less than about 100 nanoseconds. The read voltage (V_{READ}) may be between about 0.1 and 0.5 of the write voltage (V_{SET}). In some embodiments, the read currents (I_{ON} and I_{OFF}) are greater than about 1 mA or, more specifically, is greater than about 5 mA to allow for a fast detection of the state by reasonably small sense amplifiers. The length of read voltage pulse (t_{READ}) may be comparable to the length of the corresponding set voltage pulse (t_{SET}) or may be shorter than the write voltage pulse (t_{RESET}). ReRAM cells should be able to cycle between LRS and HRS between at least about 103 times or, more specifically, at least about 107 times without failure. A data retention time (t_{RET}) should be at least about 5 years or, more specifically, at least about 10 years at a thermal stress up to 85° C. and small electrical stress, such as a constant application of the read voltage (V_{READ}). Other considerations may include low current leakage, such as less than about 40 A/cm2 measured at 0.5 V per 20 Å of oxide thickness in HRS.

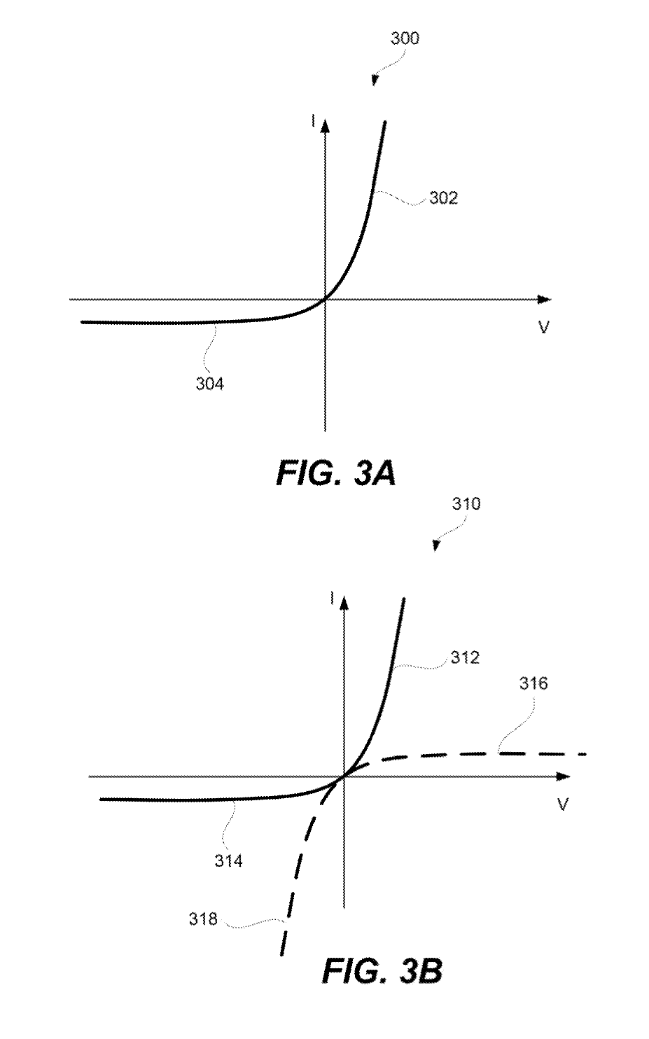

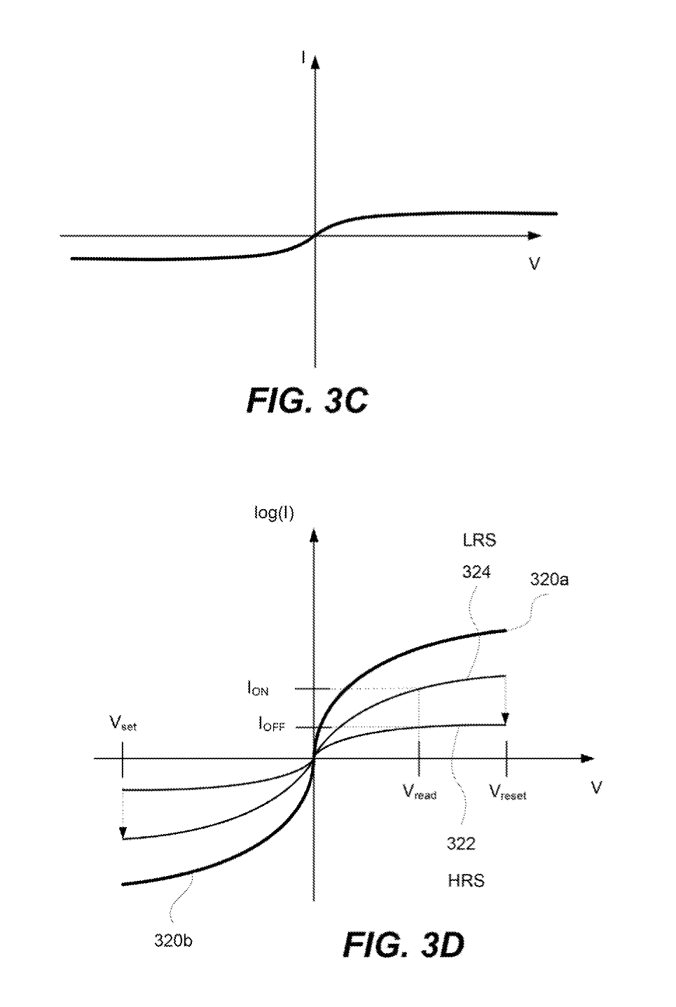

A brief description of a Schottky barrier and combining two Schottky barriers in the same ReRAM cell will now be provided. The Schottky barrier does not rely on holes or electrons recombining when they enter the opposite type of region. FIG. 3A is a plot 300 of a typical I-V characteristic of a Schottky barrier, in accordance with some embodiments. Element 302 represents a forward characteristic, while element 304 represents a reverse characteristic. Forward characteristic 302 has a low turn on voltage. At high current levels it levels off and is limited by the series resistance or the maximum level of current injection. Reverse characteristic 304 is flat with a breakdown above a certain level. The breakdown mechanism may be similar to the impact ionization breakdown in a p-n junction.

FIG. 3B is a plot 310 of I-V characteristics of two Schottky barriers connected in series, in accordance with some embodiments. The two Schottky barriers have a flipped orientation with respect to each other. The I-V characteristic of the first Schottky barrier is shown with a solid line and includes forward characteristic 312 and reverse characteristic 314. The I-V characteristic of the second Schottky barrier is shown with a dashed line and includes forward characteristic 318 and reverse characteristic 316. In this example, reverse characteristic 314 of the first Schottky barrier will dominate forward characteristic 318 of the second Schottky barrier. In a similar manner, reverse characteristic 316 of the second Schottky barrier will dominate forward characteristic 312 of the first Schottky barrier. In other words, the assembly will be primarily controlled by reverse characteristic 314 of the first Schottky barrier or by reverse characteristic 316 of the second Schottky barrier depending on the direction of the current flow through the stack containing these two Schottky barriers. It should be noted that the reverse characteristics of each Schottky barrier may be controlled in an independent manner by using different types of materials and/or design of components forming each one of the two Schottky barriers.

A combined performance of these two Schottky barriers is shown in FIG. 3C, which illustrates I-V characteristics of two Schottky barriers connected in series in an inverted manner, in accordance with some embodiments.

FIG. 3D is a combined plot of I-V characteristics of a bipolar ReRAM cell and I-V characteristics of a stack of two Schottky barriers, in accordance with some embodiments. Element 320a represents reverse characteristic of one Schottky barrier (e.g., a first Schottky barrier), while element 320b represents reverse characteristic of the other Schottky barrier (e.g., a second Schottky barrier). Element 324 represents the LRS of the ReRAM cell, while element 322 represents the HRS of the same ReRAM cell. In this assembly, the reset operation of the ReRAM cell, i.e., the switch from LRS 324 to HRS 322, will be controlled by reverse characteristic 320a of the first Schottky barrier. However, the set operation of the ReRAM cell, i.e., the switch from HRS 322 to LRS 324, will be controlled by reverse characteristic 320b of the second Schottky barrier. Each Schottky barrier may be specifically configured for the corresponding switching operation. For example, reverse characteristic 320b of the second Schottky barrier (controlling the set operation of the ReRAM cell, i.e., the switch from HRS 322 to LRS 324) may have a higher resistance than the reverse characteristic 320a of the first Schottky barrier (controlling the reset operation of the ReRAM cell, i.e., the switch from LRS 324 to HRS 322), which allows to substantially reduce the power consumption of the ReRAM cell.

### Examples of ReRAM Cells Having Schottky Barriers

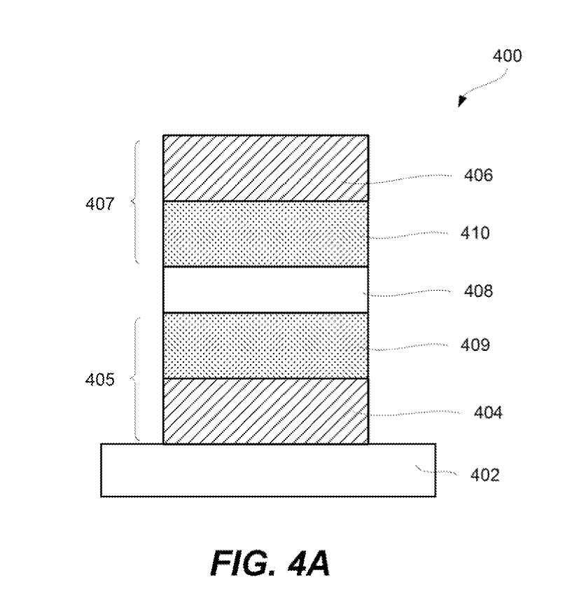

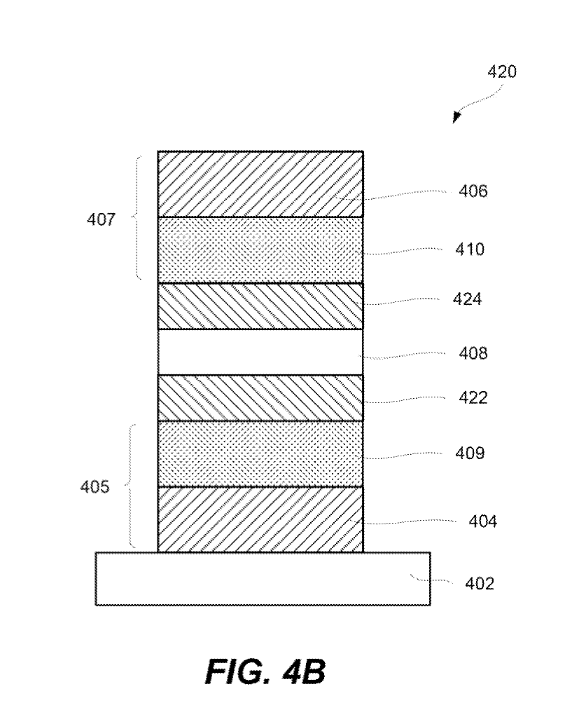

FIG. 4A is a schematic illustration of ReRAM cell 400, in accordance with some embodiments. ReRAM cell 400 may be disposed on substrate 402 that may include other ReRAM cells, layers, or structures. ReRAM cell 400 includes first electrode 404 and second electrode 406. In some embodiments, first electrode 404 and/or second electrode 406 extends laterally to connect to other ReRAM cells, for example, in a cross-bar arrangement further described below. ReRAM cell 400 also includes variable resistance layer 408 disposed between first electrode 404 and second electrode 406. Furthermore, ReRAM cell 400 includes a first semiconductor layer 409 and a second semiconductor layer 410. First semiconductor layer 409 directly interfaces first electrode 404. A combination of first semiconductor layer 409 and first electrode 404 forms a first Schottky barrier 405. Second semiconductor layer 410 directly interfaces second electrode 406. A combination of second semiconductor layer 410 and second electrode 406 forms second Schottky barrier 407. First Schottky barrier 405 may be configured to limit the electrical current flowing from first electrode 404 to second electrode 406. At the same time, second Schottky barrier 407 may be configured to limit the electrical current flowing from second electrode 406 to first electrode 404. Such combined performance of first Schottky barrier 405 and second Schottky barrier 407 is described above with reference to FIGS. 3B-3C.

In some embodiments, first semiconductor layer 409 and second semiconductor layer 410 are disposed between first electrode 404 and second electrode 406. Specifically, first semiconductor layer 409 may be disposed between first electrode 404 and variable resistance layer 408. In some embodiments, first semiconductor layer 409 may directly interface variable resistance layer 408. Alternatively, an interface layer may be disposed between first semiconductor layer 409 and variable resistance layer 408 as further described below with reference to FIG. 4B. Second semiconductor layer 410 may be disposed between second electrode 406 and variable resistance layer 408. In some embodiments, second semiconductor layer 410 may directly interface variable resistance layer 408. Alternatively, an interface layer may be disposed between second semiconductor layer 410 and variable resistance layer 408 as further described below with reference to FIG. 4B. In some embodiments, both Schottky barriers are disposed on the same side of a variable resistance layer. In other words, one Schottky barrier is disposed between about Schottky barrier and the variable resistance layer.

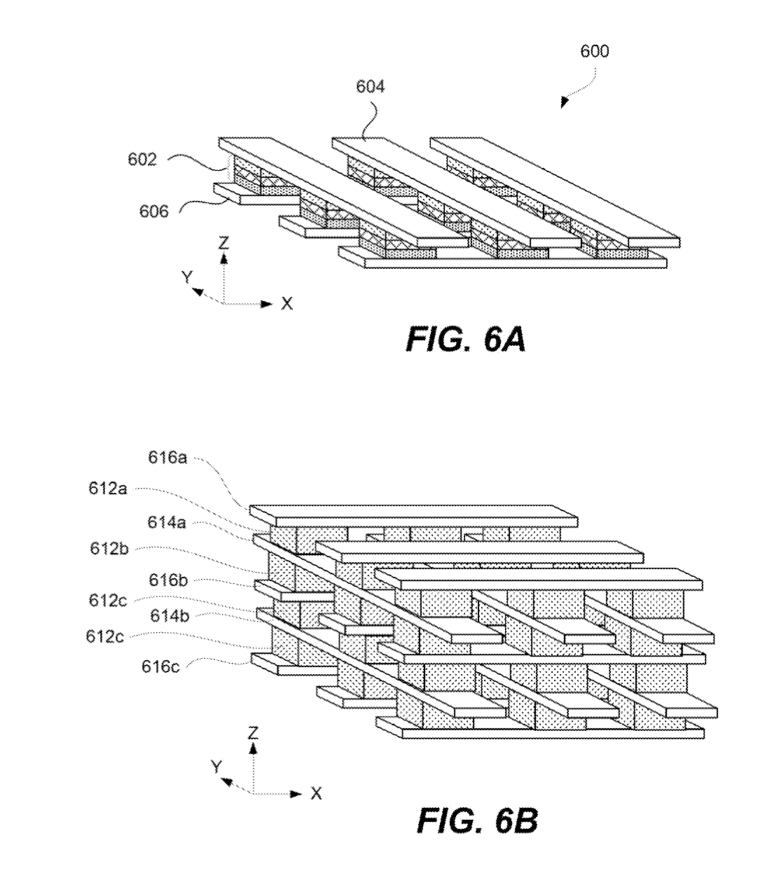

Electrodes 404 and 406 provide electrical connections to ReRAM cell 400. For example, electrodes 404 and 406 may extend between multiple ReRAM cells, which may be cells provided in the same row or the same column of a memory array as further described below with reference to FIGS. 6A and 6B. Electrodes 404 and 406 may be made from conductive materials, such as n-doped polysilicon, p-doped polysilicon, titanium nitride, ruthenium, iridium, platinum, and tantalum nitride. Electrodes 404 and 406 may have a thickness of less than about 1,000 Angstroms, such as less than about 500 Angstroms and even less than about 100 Angstroms. Thinner electrodes may be formed using ALD techniques.

Variable resistance layer 408 can be fabricated from a dielectric material, such as a metal oxide material or other similar material that can be switched between two or more stable resistive states. In some embodiments, variable resistance layer 408 is fabricated from a high bandgap material, e.g., a material that has a bandgap of at least about 4 electron Volts. Some examples of such materials include hafnium oxide (HfₓO_{y}), tantalum oxide (TaₓO_{y}), aluminum oxide (AlₓO_{y}), lanthanum oxide (LaₓO_{y}), yttrium oxide (YₓO_{y}), dysprosium oxide (DyₓO_{y}), ytterbium oxide (YbₓO_{y}) and zirconium oxide (ZrₓO_{y}). The high bandgap materials may improve data retention in ReRAM cell 300 and reduce the current leakage since the amount of trapped charge in these materials is less than a lower bandgap material. Furthermore, the high bandgap materials create a large barrier height that the carriers have to cross during the read, set, and reset operations. Other suitable materials for variable resistance layer 305 include titanium oxide (TiOₓ), nickel oxide (NiOₓ), and cerium oxide (CeOₓ). Furthermore, semi-conductive metal oxide (p-type or n-type), such as zinc oxides (ZnₓO_{y}), copper oxides (CuₓO_{y}), and their nonstoichiometric and doped variants can be used for variable resistance layer 305.

In some embodiments, variable resistance layer 408 includes a dopant that has an affinity for oxygen, such as various transition metals (e.g., aluminum, titanium, and zirconium), to form a metal-rich variable resistance layer, such as a non-stoichiometric oxide (e.g., HfO_{1.5}-HfO_{1.9} or, more specifically, HfO_{1.7}). The dopant may be the same material as a metal of the base oxide (e.g., HfO₂ doped with hafnium) or different (e.g., HfO₂ doped with aluminum, titanium, and zirconium). Oxygen deficiency of the metal-rich variable resistance layer corresponds to a number of oxygen vacancies, which are believed to be defects responsible for resistive switching. The amount of defects is controlled to achieve certain switching and forming voltages, operating currents, improve performance consistency and data retention.

Variable resistance layer 408 may have a thickness of between about 10 Angstroms to about 1000 Angstroms, such as between about 20 Angstroms and 200 Angstroms or, more specifically, between about 50 Angstroms and 100 Angstroms. Thinner variable resistance layers may be deposited using atomic layer deposition (ALD), while thicker variable resistance layers may be deposited using may be deposited using ALD as well as physical vapor deposition (PVD) and, in some embodiments, chemical vapor deposition (CVD).

First semiconductor layer 409 and first electrode 404 form first Schottky barrier 405, which limits flow of the electrical current from first electrode 404 to second electrode 406. In a similar manner, second semiconductor layer 410 and second electrode 406 form second Schottky barrier 407, which limits flow of the electrical current from second electrode 406 to first electrode 404. As such, first Schottky barrier 405 and second Schottky barrier 407 may be referred to as a pair of an inverted Schottky barriers connected in series.

In some embodiments, first semiconductor layer 409 is formed from one of silicon, a silicon containing compound, germanium, a germanium containing compound, an aluminum containing compound, a boron containing compound, a gallium containing compound, an indium containing compound, a cadmium containing compound, a zinc containing compound, a lead containing compound, or a tin containing compound. More specifically, first semiconductor layer 409 includes gallium arsenide or gallium phosphide. Alternatively, first semiconductor layer 409 may include crystalline silicon. At least a portion of this first semiconductor layer 409 may be doped with one of phosphorus, boron, or arsenic. As such, first semiconductor layer 409 may include crystalline silicon that is doped with one of phosphorus, boron, or arsenic in one area, but not the other area. This other area may be free from phosphorus, boron, and arsenic.

Likewise, second semiconductor layer 410 is formed from one of silicon, a silicon containing compound, germanium, a germanium containing compound, an aluminum containing compound, a boron containing compound, a gallium containing compound, an indium containing compound, a cadmium containing compound, a zinc containing compound, a lead containing compound, or a tin containing compound. More specifically, second semiconductor layer 410 includes gallium arsenide or gallium phosphide. Alternatively, second semiconductor layer 410 may include crystalline silicon. At least a portion of this second semiconductor layer 410 may be doped with one of phosphorus, boron, or arsenic. As such, second semiconductor layer 410 may include crystalline silicon that is doped with one of phosphorus, boron, or arsenic in one area, but not the other area. This other area may be free from phosphorus, boron, and arsenic. Other materials suitable for Schottky barriers are described above.

First Schottky barrier 405 and second Schottky barrier 407 may be configured to pass current up until the voltage between first electrode 404 and second electrode 406 is within a certain range, such as between and inclusive of the set switching voltage and the reset switching voltage. However, when the voltage between first electrode 404 and second electrode 406 is substantially outside this range, first Schottky barrier 405 or second Schottky barrier 407 may limit the current flow. For example, first Schottky barrier 405 may be configured to limit the current during a set operation corresponding to variable resistance layer 408 going from its HRS to its LRS. Without a Schottky barrier, the cell may experience a current spike and/or a voltage drop due to the sudden drop in the resistance of variable resistance layer 408. First Schottky barrier 405 is configured to limit the current spike and/or the voltage drop during the set operation. As such, first Schottky barrier 405 may be configured to pass a set electrical current flowing from first electrode 404 to second electrode 406 when a set voltage is applied between first electrode 404 and second electrode 406, but not when the voltage applied between first electrode 404 and second electrode 406 exceeds some threshold corresponding to the set voltage. For example, a set voltage may be about 1.0V and first Schottky barrier 405 may be set at 1.2V. In a similar manner, second Schottky barrier 407 may be configured to pass a reset electrical current flowing from second electrode 406 to first electrode 404 when a reset voltage is applied between first electrode 404 and second electrode 406.

In some embodiments, first Schottky barrier 405 and second Schottky barrier 407 have the same current limiting characteristics. For example, the set voltage and the reset voltage of ReRAM cell 400 may be substantially the same. Alternatively, first Schottky barrier 405 and second Schottky barrier 407 may have different current limiting characteristics because, for example, the set voltage and the reset voltage of ReRAM cell 400 are different.

In some embodiments, first Schottky barrier 405 and second Schottky barrier retain current limiting characteristics after annealing at 600° C. for 1 minute. For example, ReRAM cell may be subjected to annealing during further processing, i.e., after first Schottky barrier 405 and second Schottky barrier are formed.

FIG. 4B is a schematic illustration of another ReRAM cell 420, in accordance with some embodiments. ReRAM cell 420 may be disposed on substrate 402 that may include other ReRAM cells, layers, or structures (not shown in FIG. 4B). ReRAM cell 420 includes first electrode 404 and second electrode 406. In some embodiments, first electrode 404 and/or second electrode 406 extend laterally to connect to other ReRAM cells, for example, in a cross-bar arrangement further described below. ReRAM cell 420 also includes variable resistance layer 408 disposed between first electrode 404 and second electrode 406. Furthermore, ReRAM cell 420 includes a first semiconductor layer 409 and a second semiconductor layer 410. First semiconductor layer 409 directly interfaces first electrode 404. A combination of first semiconductor layer 409 and first electrode 404 forms a first Schottky barrier 405. Second semiconductor layer 410 directly interfaces second electrode 406. A combination of second semiconductor layer 410 and second electrode 406 forms second Schottky barrier 407. First Schottky barrier 405 may be configured to limit the electrical current flowing from first electrode 404 to second electrode 406. At the same time, second Schottky barrier 407 may be configured to limit the electrical current flowing from second electrode 406 to first electrode 404. Such combined performance of first Schottky barrier 405 and second Schottky barrier 407 is described above with reference to FIGS. 3B-3C.

ReRAM cell 420 also includes a variable resistance layer 408 and two interface layer, i.e., first interface layer 422 and second interface layer 424. First interface layer 422 is disposed between variable resistance layer 408 and first semiconductor layer 409. First interface layer 422 may be used as a diffusion barrier that prevents migration of materials between variable resistance layer 408 and first semiconductor layer 409 and, in some embodiments, between first interface layer 422 and variable resistance layer 408. Alternatively, first interface layer 422 may be used as a source and/or as a sink of oxygen vacancies to variable resistance layer 408. As such, first interface layer 422 may be operable as an inner electrode. Furthermore, in some embodiments, a first Schottky barrier may be formed at an interface of first interface layer 422 and first semiconductor layer 409 rather than at an interface of first electrode 404 and first semiconductor layer 409. In a similar manner, a second Schottky barrier may be formed at an interface of second interface layer 424 and second semiconductor layer 410 rather than at an interface of second electrode 406 and second semiconductor layer 410.

Likewise, second interface layer 421 is disposed between variable resistance layer 408 and second semiconductor layer 410. Second interface layer 424 may be used as a diffusion barrier that prevents migration of materials between variable resistance layer 408 and second semiconductor layer 410 and, in some embodiments, between second interface layer 424 and variable resistance layer 408. Alternatively, second interface layer 424 may be used as a source and/or as a sink of oxygen vacancies to variable resistance layer 408. As such, second interface layer 424 may be operable as an inner electrode.

In some embodiments, only one interface layer is present and variable resistance layer 408 interfaces with one semiconductor layer forming one Schottky barrier but not another semiconductor layer forming another Schottky barrier.

### Processing Examples

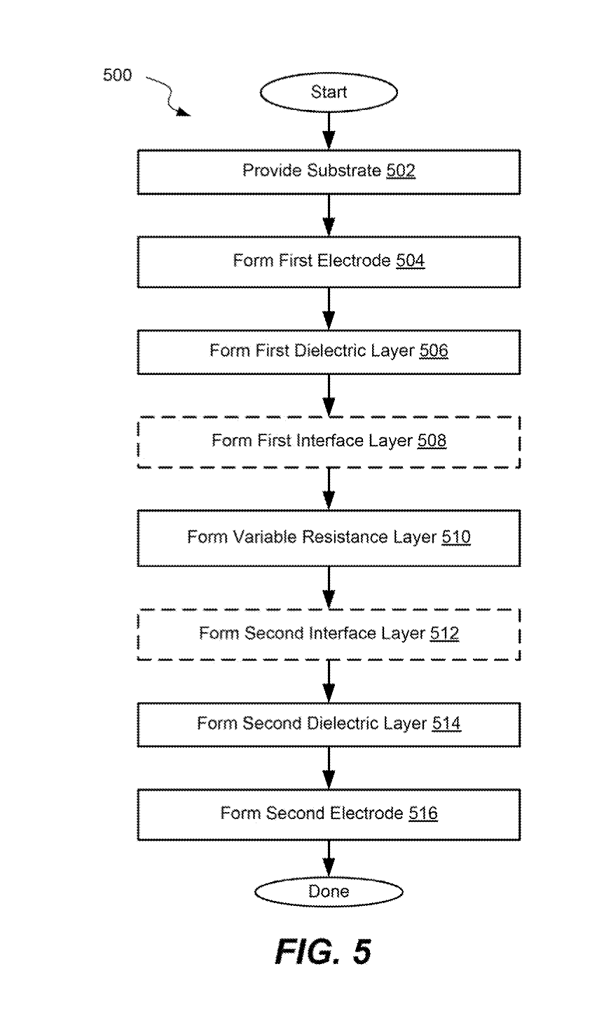

FIG. 5 illustrates a process flow chart corresponding to method 500 of fabricating a resistive random access memory cell including two inverted Schottky barriers disposed in a stack with a variable resistance layer, in accordance with some embodiments. Method 500 may commence with providing a substrate during operation 502. In some embodiments, the substrate may include a first electrode and a variable resistance layer, in which case method 500 may proceed with forming a semiconductor layer during operation 506. Alternatively, method 500 may proceed with forming a first electrode on the substrate during optional operation 504 and then forming a semiconductor layer over the first electrode during operation 506.

In some embodiments, operation 504 may involve forming a titanium nitride electrode using sputtering. Deposition of the titanium nitride electrode may be performed using a titanium target in a nitrogen atmosphere maintained at a pressure of between about 1-20 mTorr. The power density may be maintained at 3.3-11 W/cm² (150-500 Watts on a 3″ diameter target) that may result in a deposition rate of about 0.5-5 Angstroms per second (depending on the size of the target sample and other process parameters). Some of the provided process parameters are for illustrative purposes only and generally depend on deposited materials, tools, deposition rates, and other factors.

Method 500 may proceed with forming a first semiconductor layer during operation 506. For example, gallium arsenide or gallium phosphide may be formed using PVD, ALD, PLD, or CVD. The first semiconductor layer is formed over the first electrode and these two layers form a first Schottky barrier as describe above. In some embodiments, method 500 involves optional operation 508 during which a first interface layer is formed on the first semiconductor layer. Alternatively, method 500 proceeds with operation 510 and the first semiconductor layer is not formed.

Method 500 may proceed with forming a variable resistance layer during operation 510. The variable resistance layer may be deposited using PVD or other suitable techniques. For example, a hafnium oxide layer having a thickness of between about 5-500 Angstroms may be formed using reactive sputtering by employing a metal hafnium target in a 20-60% oxygen atmosphere. Power of 100-1000 Watts (W) may be used to achieve deposition rates of between about 0.1 and 1.0 Angstroms per second. These process parameters are provided as examples and generally depend on deposited materials, tools, deposition rates, and other factors. Other processing techniques, such as ALD, PLD, CVD, evaporation, and the like can also be used to deposit the variable resistance layer. For example, ALD can be used to form a hafnium oxide layer using hafnium precursors, such as tetrakis (diethylamido) hafnium (TDEAHf), tetrakis (dimethylamido) hafnium (TDMAHf), tetrakis (ethylmethylamido) hafnium (TEMAHf) or hafnium chloride (HfCl₄), and a suitable oxidant, such as water, oxygen plasma, or ozone.

A variable resistance layer may include multiple metals. For example, one metal may be used to dope an oxide of another metal. Two or more metals may be co-deposited to form one common layer or deposited in sequences to form multiple sub-layers of the variable resistance layer. For example, PVD may be used to deposit a layer containing hafnium oxide and aluminum oxide. Specifically, a co-sputtering arrangement using either a hafnium target and an aluminum target in an oxygen containing atmosphere or a hafnium oxide target and an aluminum oxide target may be used. In another example, ALD may be used to co-inject hafnium and aluminum precursors at desired proportions to co-deposit a metal oxide layer or to form multiple sub-layers. In some embodiments, operation 510 may involve ion implantation. The ion implantation can isovalently or aliovalently dope the variable resistance layer and can reduce forming voltages, improve set and reset voltage distributions, and increase device yield.

In some embodiments, the variable resistance layer may be formed using an MOCVD technique. For example, the variable resistance layer may include one or two oxides configured to resistively switch when switching voltages are applied to the layer. When multiple oxides are used, these oxides may have various distribution profiles. For example, one oxide may have a peak concentration away from the interface surface of the variable resistance layer. When the variable resistance layer is formed using MOCVD, the embedded resistor may be formed in situ in the same deposition chamber. As such, the embedded resistor and the variable resistance layer may be formed in two sequential operations or even a single operation without exposing a partially fabricated ReRAM to the environment in between these depositions.

Method 500 may involve forming a second interface during optional operation 512. This operation would be understood by one having ordinary skills in the art and, in some embodiments, may the same as or similar to operation 508 described above. Furthermore, method 500 may involve forming a second semiconductor layer during operation 514. This operation would be understood by one having ordinary skills in the art and, in some embodiments, may the same as or similar to operation 506 described above. Finally, method 500 may proceed with forming a second electrode during operation 516. This operation would be understood by one having ordinary skills in the art and, in some embodiments, may the same as or similar to operation 504 described above.

### Memory Array Examples

A brief description of memory arrays will now be described with reference to FIGS. 6A and 6B to provide better understanding of various aspects of thermally isolating structures provided adjacent to ReRAM cells and, in some examples, surrounding the ReRAM cells. ReRAM cells described above may be used in memory devices or larger integrated circuits (IC) that may take a form of arrays. FIG. 6A illustrates a memory array 600 including nine ReRAM cells 602, in accordance with some embodiments. In general, any number of ReRAM cells may be arranged into one array. Connections to each ReRAM cell 602 are provided by signal lines 604 and 606, which may be arranged orthogonally to each other. ReRAM cells 602 are positioned at crossings of signal lines 604 and 606 that typically define boundaries of each ReRAM cell in array 600.

Signal lines 604 and 606 are sometimes referred to as word lines and bit lines. These lines are used to read and write data into each ReRAM cell 602 of array 600 by individually connecting ReRAM cells to read and write controllers. Individual ReRAM cells 602 or groups of ReRAM cells 602 can be addressed by using appropriate sets of signal lines 604 and 606. Each ReRAM cell 602 typically includes multiple layers, such as top and bottom electrodes, variable resistance layer, embedded resistors, embedded current steering elements, and the like, some of which are further described elsewhere in this document. In some embodiments, a ReRAM cell includes multiple variable resistance layers provided in between a crossing pair of signal lines 604 and 606.

As stated above, various read and write controllers may be used to control operations of ReRAM cells 602. A suitable controller is connected to ReRAM cells 602 by signal lines 604 and 606 and may be a part of the same memory device and circuitry. In some embodiments, a read and write controller is a separate memory device capable of controlling multiple memory devices, each one containing an array of ReRAM cells. Any suitable read and write controller and array layout scheme may be used to construct a memory device from multiple ReRAM cells. In some embodiments, other electrical components may be associated with the overall array 600 or each ReRAM cell 602. For example, to avoid the parasitic-path-problem, i.e., signal bypasses by ReRAM cells in their low resistance state (LRS), serial elements with a particular non-linearity must be added at each node or, in some embodiments, into each element. Depending on the switching scheme of the ReRAM cell, these elements can be diodes or varistor-type elements with a specific degree of non-linearity. In the same other embodiments, an array is organized as an active matrix, in which a transistor is positioned at each node or, in some embodiments, embedded into each cell to decouple the cell if it is not addressed. This approach significantly reduces crosstalk in the matrix of the memory device.

In some embodiments, a memory device may include multiple array layers as, for example, illustrated in FIG. 6B. In this example, five sets of signal lines 614a-b and 616a-c are shared by four ReRAM arrays 612a-c. As with the previous example, each ReRAM array is supported by two sets of signal lines, e.g., array 612a is supported by 614a and 616a. However, middle signal lines 614a-b and 616b, each is shared by two sets of ReRAM arrays. For example, signal line set 614a provides connections to arrays 612a and 612b. Top and bottom sets of signal lines 616a and 616c are only used for making electrical connections to one array. This 3-D arrangement of the memory device should be distinguished from various 3-D arrangements in each individual ReRAM cell.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

What is claimed:

1. A resistive random access memory (ReRAM) cell comprising:
a first conductive layer;
a second conductive layer;
a variable resistance layer between the first conductive layer and the second conductive layer;
a first semiconductor layer between the first conductive layer and the variable resistance layer; and
a second semiconductor layer between the second conductive layer and the variable resistance layer,
wherein the first conductive layer and the second conductive layer are operable as electrodes;
wherein the first semiconductor layer and the first conductive layer form a first Schottky barrier;
wherein the second semiconductor layer and the second conductive layer form a second Schottky barrier;
wherein the first Schottky barrier is operable to limit an electrical current from the first conductive layer to the second conductive layer, and
wherein the second Schottky barrier is operable to limit an electrical current from the second conductive layer to the first conductive layer.

2. The ReRAM cell of claim 1, wherein the first semiconductor layer directly interfaces the variable resistance layer.

3. The ReRAM cell of claim 2, wherein the second semiconductor layer directly interfaces the variable resistance layer.

4. The ReRAM cell of claim 1, further comprising a first intermediate conductive layer disposed between the first semiconductor layer and the variable resistance layer.

5. The ReRAM cell of claim 4, further comprising a second intermediate conductive layer disposed between the second semiconductor layer and the variable resistance layer.

6. The ReRAM cell of claim 4, wherein the first semiconductor layer directly interfaces the variable resistance layer.

7. The ReRAM cell of claim 1, wherein the first conductive layer comprising one of aluminum, copper, gold, silver, nickel, palladium, platinum, chromium, molybdenum, tungsten, titanium, or indium.

8. The ReRAM cell of claim 1, wherein the first semiconductor layer comprises one of silicon, a silicon containing compound, germanium, a germanium containing compound, an aluminum containing compound, a boron containing compound, a gallium containing compound, an indium containing compound, a cadmium containing compound, a zinc containing compound, a lead containing compound, or a tin containing compound.

9. The ReRAM cell of claim 1, wherein the first semiconductor layer comprises gallium arsenide or gallium phosphide.

10. The ReRAM cell of claim 1, wherein the first semiconductor layer comprises crystalline silicon and wherein at least a portion of the first semiconductor layer is doped with one of phosphorus, boron, or arsenic.

11. The ReRAM cell of claim 1, wherein the ReRAM cell is a bi-polar cell.

12. The ReRAM cell of claim 11, wherein the first Schottky barrier is operable to pass a set electrical current flowing from the first conductive layer to the second conductive layer when a set voltage is applied between the first conductive layer and the second conductive layer.

13. The ReRAM cell of claim 12, wherein the second Schottky barrier is operable to pass a reset electrical current flowing from the second conductive layer to the first conductive layer when a reset voltage is applied between the first conductive layer and the second conductive layer.

14. The ReRAM cell of claim 11, wherein the first Schottky barrier has a same current limiting characteristic as the second Schottky barrier.

15. The ReRAM cell of claim 11, wherein the first Schottky barrier has a different current limiting characteristic than the second Schottky barrier.

16. The ReRAM cell of claim 1, wherein the variable resistance layer has a variable composition in a direction from the first conductive layer to the second conductive layer.

17. The ReRAM cell of claim 1, wherein the variable resistance layer comprises one of silicon oxide, aluminum oxide, hafnium oxide, or zirconium oxide.

18. The ReRAM cell of claim 17, wherein a concentration of oxygen is less at a surface of the variable resistance layer facing toward the first conductive layer than at a surface of the variable resistance layer facing toward the second conductive layer.

19. The ReRAM cell of claim 1, wherein the first Schottky barrier and the second Schottky barrier retain current limiting characteristics after annealing at 600° C. for 1 minute.

20. A method of fabricating a resistive random access memory (ReRAM) cell, the method comprising:
forming a first conductive layer;
forming a first semiconductor layer over the first conductive layer;
forming a variable resistance layer over the first semiconductor layer;
forming a second semiconductor layer over the variable resistance layer; and
forming a second conductive layer over the second semiconductor layer,
wherein the first conductive layer and the second conductive layer are operable as electrodes,
wherein the first semiconductor layer and the first conductive layer form a first Schottky barrier; and
wherein the second semiconductor layer and the second conductive layer form a second Schottky barrier.
